(19) United States
(12) Patent Application Publication
(10) Pub. No.: US 2015/0156921 A1
(43) Pub. Date: Jun. 4, 2015

(54) ELECTRICAL SYSTEM, ELECTRICAL SYSTEM CONTROL METHOD, AND COOLING APPARATUS

(71) Applicant: FUJITSU LIMITED, Kawasaki-shi (JP)

(72) Inventor: Toru YOKOHATA, Shinagawa (JP)

(73) Assignee: FUJITSU LIMITED, Kawasaki-shi (JP)

(21) Appl. No.: 14/551,362

(22) Filed: Nov. 24, 2014

(30) Foreign Application Priority Data
Dec. 4, 2013 (JP) 2013-251311

(51) Int. Cl. H05K 7/20

(52) U.S. Cl. CPC H05K 7/20218; H05K 7/20281

(57) ABSTRACT

An electrical system comprising a plurality of sets of electrical devices and cooling units that respectively cool the electrical devices, wherein: each of the cooling units includes a tank that is connected via a connection pipe to another tank of another of the cooling units and that stores coolant; a heat exchanger that cools the coolant from the tank; and a pump that feeds the coolant, which has been cooled by the heat exchanger, via a circulation pipe to the tank, the heat exchanger, and a cooler that cools a respective one of the electrical devices.

### CROSS-REFERENCE TO RELATED APPLICATION

This application is based upon and claims the benefit of priority of the prior Japanese Patent Application No. 2013-251311, filed on Dec. 4, 2013, the entire contents of which are incorporated herein by reference.

### FIELD

The embodiments discussed herein are related to an electrical system, an electrical system control method, and a cooling apparatus.

### BACKGROUND

In a water supply system that supplies water by pump to a tank installed, for example, in a high rise building, a known water supply system includes a reserve pump that operates when a pump malfunctions (see, for example, Japanese Laid-Open Patent Publication No. 11-61897).

In an electrical system to cool an electrical device with coolant, a known electrical system includes two cooling units that supply coolant to an electrical device (see, for example, Japanese Laid-Open Patent Publication No. 2005-191554). In this electrical system, when a pump in one cooling unit malfunctions, coolant liquid continues to be supplied to the electrical device by operating a reserve pump of the other cooling unit.

### SUMMARY

According to an aspect of the embodiments, an electrical system comprising a plurality of sets of electrical devices and cooling units that respectively cool the electrical devices, wherein: each of the cooling units includes a tank that is connected via a connection pipe to another tank of another of the cooling units and that stores coolant; a heat exchanger that cools the coolant from the tank; and a pump that feeds the coolant, which has been cooled by the heat exchanger, via a circulation pipe to the tank, the heat exchanger, and a cooler that cools a respective one of the electrical devices.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram illustrating an electrical system according to an embodiment;

FIG. 2 is a schematic configuration diagram illustrating the cooling unit illustrated in FIG. 1;

FIG. 3 is a cross-section illustrating the sealed expansion tank illustrated in FIG. 2;

FIG. 4 is a cross-section illustrating plural sealed expansion tanks illustrated in FIG. 1;

FIG. 5 is a schematic diagram illustrating a cooling apparatus according to a Comparative Example;

FIG. 6 is a schematic diagram illustrating a cooling apparatus according to a Comparative Example;

FIG. 7 is a schematic diagram illustrating a modified example of the cooling unit illustrated in FIG. 1; and

FIG. 8 is a schematic diagram illustrating a modified example of the cooling unit illustrated in FIG. 1.

### DESCRIPTION OF EMBODIMENTS

Explanation follows regarding an embodiment of technology disclosed herein, with reference to the drawings.

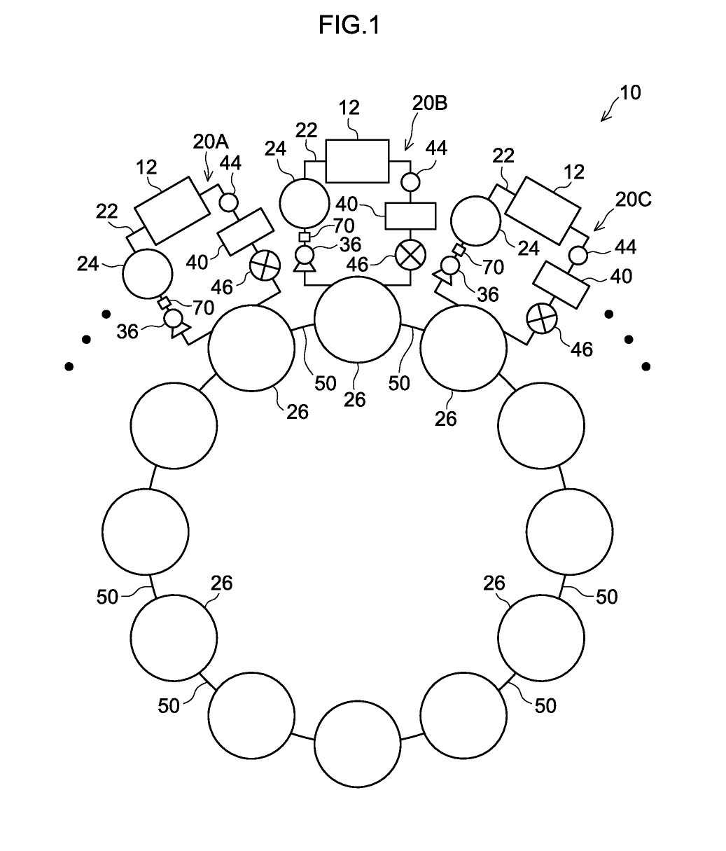

As illustrated in FIG. 1, an electrical system 10 according to the present embodiment includes plural sets of electrical devices 12, and cooling units 20 that cool the electrical devices 12. In FIG. 1, only some of the cooling units 20 are illustrated, namely the cooling units 20A, 20B, 20C.

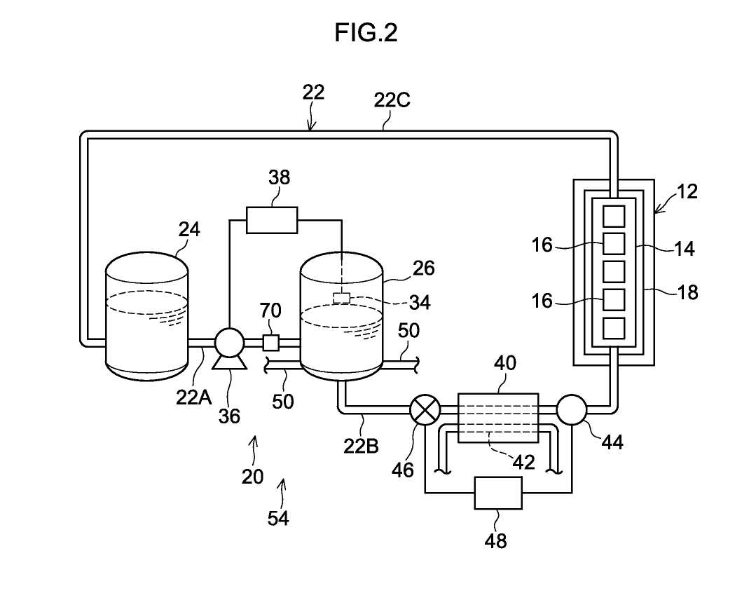

As illustrated in FIG. 2, each of the electrical devices 12 is, for example, a data processing device, such as a server, including a board 14 and a cooler 18. Plural electrical components 16, such as a CPU and storage memory, are mounted on the board 14. The electrical components 16 are examples of a heat generating section, and consume power and generate heat.

Each of the coolers 18 is, for example, configured by a cooling plate or a water block, and is disposed to enable heat exchange with the electrical components 16. The insides of the coolers 18 are formed with internal flow paths, not illustrated in the drawings, that are supplied with coolant liquid from a supply pipe 22B, described below. Each of the electrical components 16 is cooled by heat exchange between the plural electrical components 16 mounted to the board 14 and the coolant liquid flowing in the internal flow paths.

The cooling units 20 are devices that supply coolant liquid to the cooler 18 of each of the electrical devices 12. The cooling units 20 include a circulation pipe 22, a recovery tank 24, a sealed expansion tank 26, a pump 36, a heat exchanger 40, a flow sensor 44, and a flow rate regulation valve 46. The cooling units 20 each have the same configuration.

The circulation pipe 22 is a pipe that circulates coolant liquid, such as water, between the recovery tank 24, the sealed expansion tank 26, the heat exchanger 40, and the cooler 18 of the electrical device 12. The circulation pipe 22 is formed by supply pipes 22A, 22B and a discharge pipe 22C. The coolant liquid is an example of a coolant.

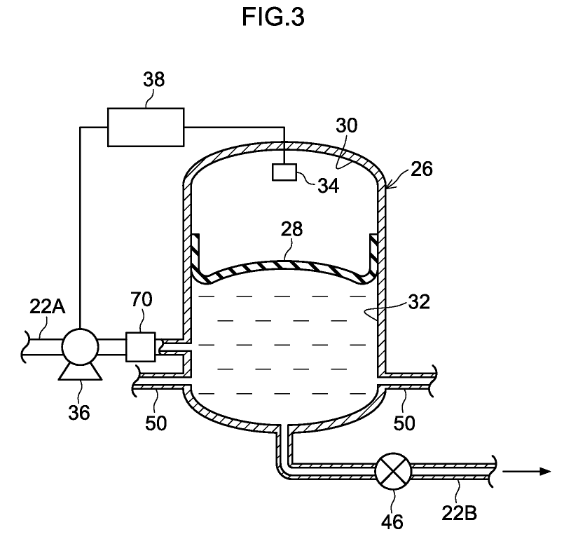

The sealed expansion tank 26 is connected to the recovery tank 24 via the supply pipe 22A. The sealed expansion tank 26, as illustrated in FIG. 3, has an internal sealed space. The inside (sealed space) of the sealed expansion tank 26 is separated into a gas chamber 30 and a reservoir 32 by a dividing membrane 28. The dividing membrane 28 is, for example, formed from a rubber sheet or the like. The sealed expansion tank 26 is an example of a tank.

The gas chamber 30 is filled with air, or nitrogen or the like. A pressure sensor 34 is provided to the gas chamber 30 as an example of a detector. The pressure sensor 34 detects the pressure in the gas chamber 30, and outputs the detected pressure to a controller 38.

The reservoir 32, as illustrated in FIG. 2, is connected to the recovery tank 24 via the supply pipe 22A. Coolant liquid supplied from the recovery tank 24 via the supply pipe 22A is stored in the reservoir 32. The cooler 18 of the electrical device 12 is connected to the reservoir 32 via the supply pipe 22B. The dividing membrane 28 elastically deforms, and the pressure (hydrostatic pressure) of the gas chamber 30 changes as the amount of coolant liquid stored in the reservoir 32 varies. More specifically, the pressure in the gas chamber 30 drops as the amount of coolant liquid stored in the reservoir 32 decreases. In contrast, the pressure in the gas chamber 30 rises as the amount of coolant liquid stored in the reservoir 32 increases. Changes in the pressure of the gas chamber 30 are detected by the pressure sensor 34.

The pump 36 is connected to the supply pipe 22A. The pump 36 includes, for example, an inverter motor (not illustrated in the drawings). The coolant liquid in the recovery tank 24 is fed out via the supply pipe 22A to the reservoir 32 of the sealed expansion tank 26 by driving this motor. The controller 38 that controls the revolutions of the motor is electrically connected to the pump 36.

Note that a non-reverse valve 70 is provided to the supply pipe 22A. The non-reverse valve 70 permits flow of coolant liquid flowing in the supply pipe 22A from the recovery tank 24 to the sealed expansion tank 26, and stops flow of coolant liquid from the sealed expansion tank 26 to the recovery tank 24. Various configurations of non-reverse valve may be employed as the non-reverse valve 70.

The controller 38 includes, for example, an inverter control circuit. The controller 38 controls operation of the pump 36 so as to discharge coolant liquid in the reservoir 32 via the supply pipe 22B according to the pressure of the gas chamber 30 in the sealed expansion tank 26. The controller 38 thereby varies the circulation rate of coolant liquid circulating in the circulation pipe 22.

More specifically, a target pressure value for the pressure of the gas chamber 30 is pre-set in the controller 38. The target pressure value is a pressure value of the gas chamber 30 that enables at least the designated flow rate of the coolant liquid employed in cooling the electrical components 16 of the electrical device 12 to be discharged from the reservoir 32 to the supply pipe 22B. The pressure sensor 34 is electrically connected to the controller 38. The controller 38 drives the motor of the pump 36, or increases the revolutions of the motor, if the pressure of the gas chamber 30 input from the pressure sensor 34 is less than the target pressure value. However, the controller 38 stops the motor of the pump 36, or reduces the revolutions of the motor, if the pressure in the gas chamber 30 input from the pressure sensor 34 is equal to or greater than the target pressure value. The pressure of the gas chamber 30 is thereby maintained in the vicinity of the target pressure value.

The target pressure value is an example of a predetermined value. The predetermined value may, for example, be a target pressure range. The pressure of the gas chamber 30 may be controlled by operating the pump 36 using the controller 38 so as fall within the target pressure range.

As illustrated in FIG. 2, the heat exchanger 40 that cools the coolant liquid is connected to the supply pipe 22B that connects the reservoir 32 of the sealed expansion tank 26 to the cooler 18 of the electrical device 12. The heat exchanger 40 includes a cooling flow path 42 supplied with cooling water from a water source, not illustrated in the drawings. The cooling water is at a lower temperature than the coolant liquid flowing in the supply pipe 22B. The coolant liquid is cooled by heat exchange between the cooling water and the coolant liquid in the supply pipe 22B.

The flow sensor 44 is provided in the supply pipe 22B between the heat exchanger 40 and the electrical device 12, as an example of a flow rate detection section. The flow sensor 44 detects the flow rate of the coolant liquid in the supply pipe 22B, and outputs the detected flow rate of the coolant liquid to a flow rate controller 48, described below.

The flow rate regulation valve 46 is provided in the supply pipe 22B between the heat exchanger 40 and the sealed expansion tank 26, as an example of a flow rate regulator. The flow rate regulation valve 46 varies the flow rate of the coolant liquid flowing in the supply pipe 22B by opening and closing of a valve, not illustrated in the drawings. The flow rate controller 48 is electrically connected to the flow rate regulation valve 46.

The flow rate controller 48 includes, for example, electrical circuits and the like. A target flow rate value (designated flow rate value) of the coolant liquid employed for cooling the electrical components 16 of the electrical device 12 is pre-set in the flow rate controller 48. The flow rate controller 48 opens and closes the valve of the flow rate regulation valve 46 such that the flow rate of the coolant liquid input from the flow sensor 44 becomes the target flow rate value.

More specifically, the flow rate controller 48 increases the opening amount of the valve of the flow rate regulation valve 46 and increases the flow rate of the coolant liquid if the flow rate of the coolant liquid input from the flow sensor 44 is less than the target flow rate value. However, the flow rate controller 48 decreases the opening amount of the valve of the flow rate regulation valve 46 and decreases the flow rate of the coolant liquid if the flow rate of the coolant liquid input from the flow sensor 44 is greater than the target flow rate value. The flow rate of the coolant liquid supplied to the cooler 18 of the electrical device 12 is thereby maintained in the vicinity of the target flow rate.

The flow rate regulation valve 46 and the flow sensor 44 in the supply pipe 22B may be provided at either the downstream side or the upstream side with respect to the heat exchanger 40.

As illustrated in FIG. 1, the reservoirs 32 of the cooling units 20 are connected together in a ring by connection pipes 50. The coolant liquid is accordingly transferable between the reservoirs 32 of adjacent sealed expansion tanks 26. In the present embodiment, a cooling apparatus 54 includes the connection pipes 50 and plural of the cooling units 20.

In the present embodiment, a maximum feed rate (maximum liquid feed rate) is set for each of the pumps 36 so that cooling of the electrical components 16 is still possible for all of the plural electrical devices 12 by the remaining pumps 36, even if at least one but less than all of the pumps 36 among the cooling units 20 are stopped. In other words, in the present embodiment, the maximum feed rate (maximum liquid feed rate) is set for each of the pumps 36 so as to permit stoppage of at least one but less than all of the pumps 36 among the cooling units 20.

More specifically, a maximum feed rate U is set for each of the pumps 36 of the plural pumps 36, such that a total sum S of the maximum feed rates of at least one but less than all of the pumps 36 is equal to or greater than a total sum T of the designated flow rate of the coolant liquid employed in the cooling by the coolers 18 of the plural electrical devices 12 (S≧T).

To give a more specific example, in the present embodiment there are twelve of the pumps 36 to twelve of the electrical devices 12. Out of the twelve pumps 36, if, for example, stoppage of one of the pumps 36 is permitted, then a maximum feed rate U₁ of each of the pumps 36 is set such that the total sum S of the maximum feed rate U₁ for eleven (=12−1) of the pumps 36 is equal to or greater than the total sum T of the designated flow rate of twelve of the electrical devices 12 (≧T/11). If, for example, stoppage of two of the pumps 36 is permitted, then a maximum feed rate U₂ of each of the pumps 36 is set such that the total sum S of the maximum feed rate U₂ for ten (=12−2) of the pumps 36 is equal to or greater than the total sum T of the designated flow rate of twelve of the electrical devices 12 (≧T/10). The above specific example is a case in which the maximum feed rate is set the same for each of the pumps 36; however, it is possible to set the maximum feed rate differently for each of the plural pumps 36.

Explanation next follows regarding an example of an electrical system control method according to the present embodiment.

As illustrated in FIG. 2, in the present embodiment, operation of the pumps 36 of the respective cooling units 20 supplies coolant liquid inside the recovery tank 24 to the reservoir 32 of the sealed expansion tank 26 via the supply pipe 22A. When this occurs, the controller 38 of each of the cooling units 20 varies the revolutions of the motor of the pump 36 (not illustrated in the drawings) such that the pressure of the gas chamber 30 of the sealed expansion tank 26 becomes the target pressure value. As a result, the pressure of the gas chamber 30 is maintained in the vicinity of the target pressure value. The coolant liquid in the reservoir 32 of each of the sealed expansion tanks 26 is accordingly continuously discharged from the supply pipe 22B due to the pressure of the gas chamber 30. The coolant liquid does not readily flow in the connection pipes 50 due to the pressures of the gas chambers 30 being maintained at the same target pressure value vicinity for all of the sealed expansion tanks 26.

The coolant liquid discharged to the supply pipe 22B is regulated in flow by the flow rate regulation valve 46 and then passes via the heat exchanger 40. When this occurs, the coolant liquid is cooled by heat exchange between the coolant liquid flowing via the supply pipe 22B and the cooling water flowing via the cooling flow path 42 of the heat exchanger 40.

The coolant liquid cooled in the heat exchanger 40 is then supplied to the cooler 18 of the electrical device 12. The electrical components 16 are then cooled by heat exchange between the coolant liquid flowing in the cooler 18 and the electrical components 16 of the electrical devices 12. The coolant liquid discharged from the cooler 18 is then recovered in the recovery tank 24 via the discharge pipe 22C.

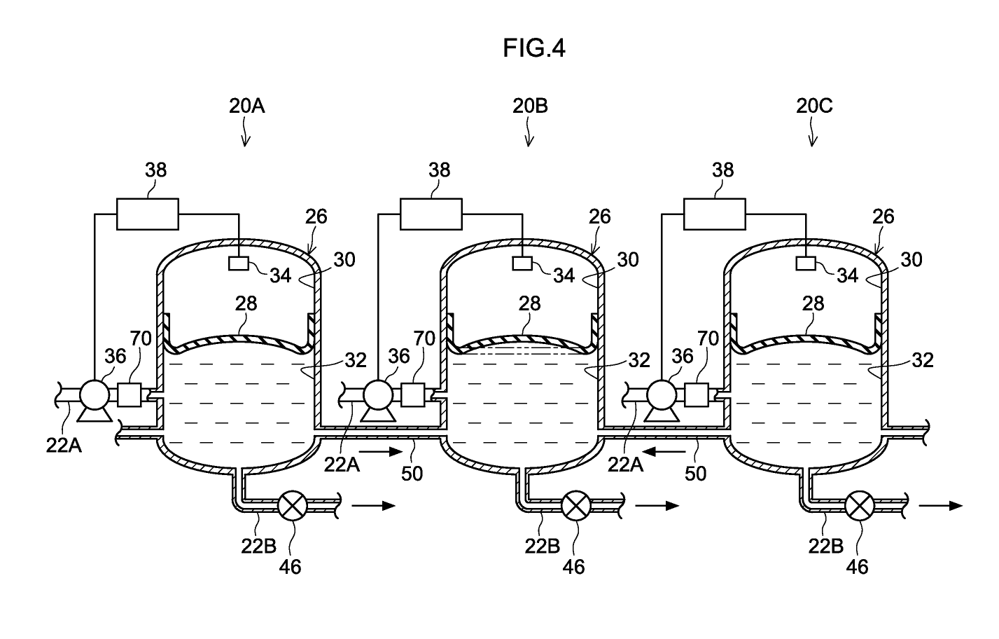

The reservoirs 32 of the sealed expansion tanks 26 of adjacent cooling units 20 are connected by the connection pipes 50. Accordingly, as illustrated in FIG. 4, if the pump 36 of the cooling unit 20B stops, such as due to a malfunction, the following occurs. In FIG. 4, for convenience, three adjacent cooling units 20 are denoted as the cooling units 20A, 20B, 20C, in sequence from the left.

Namely, if the pump 36 of the cooling unit 20B stops, the pressure of the gas chamber 30 of the cooling unit 20B falls due to coolant liquid ceasing to be supplied from the pump 36 to the reservoir 32. In FIG. 4, a state in which the pressure of the gas chamber 30 of the cooling unit 20B has fallen and the dividing membrane 28 has deformed is illustrated by double-dashed intermittent lines. Even though the pump 36 has stopped, backflow of the coolant liquid to the supply pipe 22A is prevented by the non-reverse valve 70.

As a result, coolant liquid is supplied from the reservoirs 32 of the adjacent cooling units 20A, 20C, via the connection pipes 50, to the reservoir 32 of the cooling unit 20B. The pressure in the gas chambers 30 in each of the cooling units 20A, 20C accordingly attempts to drop due to the increase in the discharge rate of coolant liquid from the reservoirs 32.

As previously described, in the present embodiment, the maximum feed rate of each of the pumps 36 is set so as to permit stoppage of at least one but less than all of the pumps 36 among the cooling units 20. Namely, the liquid feed capability of the pumps 36 of each of the cooling units 20A, 20B, 20C has excess remaining capacity (spare capacity) with respect to the designated flow rates for the electrical devices 12 connected to the cooling units 20A, 20B, 20C.

Accordingly, if the pressure in the reservoirs 32 of the cooling units 20A, 20C attempts to drop, the controller 38 of each of the cooling units 20A, 20C increases the flow rate of the coolant liquid supplied to the reservoirs 32 using the excess liquid feed capability of the pumps 36. More specifically, the controller 38 of each of the cooling units 20A, 20C increases the revolutions of the motor of the pump 36 such that the pressure in the gas chamber 30 becomes the target pressure value, increasing the feed rate of the coolant liquid.

The pressure in the gas chamber 30 of each of the cooling units 20A, 20C is accordingly maintained in the vicinity of the target pressure value, and the pressure in the gas chamber 30 of the cooling unit 20B is also maintained in the vicinity of the target pressure value. Coolant liquid accordingly continues to be fed into the coolers 18 of the electrical devices 12 from each of the cooling units 20A, 20B, 20C. The pumps 36 of the other cooling units 20 also operate in a similar manner to the pump 36 of each of the cooling units 20A, 20C.

Thus the present embodiment enables at least one but less than all of the pumps 36 among the cooling units 20 to be permitted to stop. Namely, the present embodiment enables redundancy in the pumps 36. The present embodiment accordingly enables the reliability of supply of coolant liquid to the electrical components 16 of each of the electrical devices 12 to be raised. The present embodiment accordingly enables coolant liquid to be continuously fed to the electrical components 16 of each of the electrical devices 12 without employing a reserve pump (a standby pump).

In the present embodiment, the sealed expansion tanks 26 of the cooling units 20 are connected together in a ring by the connection pipes 50. Thus, even if one or other of the pumps 36 were to stop, coolant liquid is supplied from the reservoirs 32 of the two other adjacent sealed expansion tanks 26 to the reservoir 32 of the sealed expansion tank 26 connected to the stopped pump 36. The feed rate of the cooling unit 20 whose pump 36 has stopped can thereby be recovered quickly.

Explanation next follows regarding operation of the present embodiment, in comparison to Comparative Examples. Configuration in each of the Comparative Examples similar to that of the present embodiment is allocated the same reference numerals and further explanation thereof is omitted.

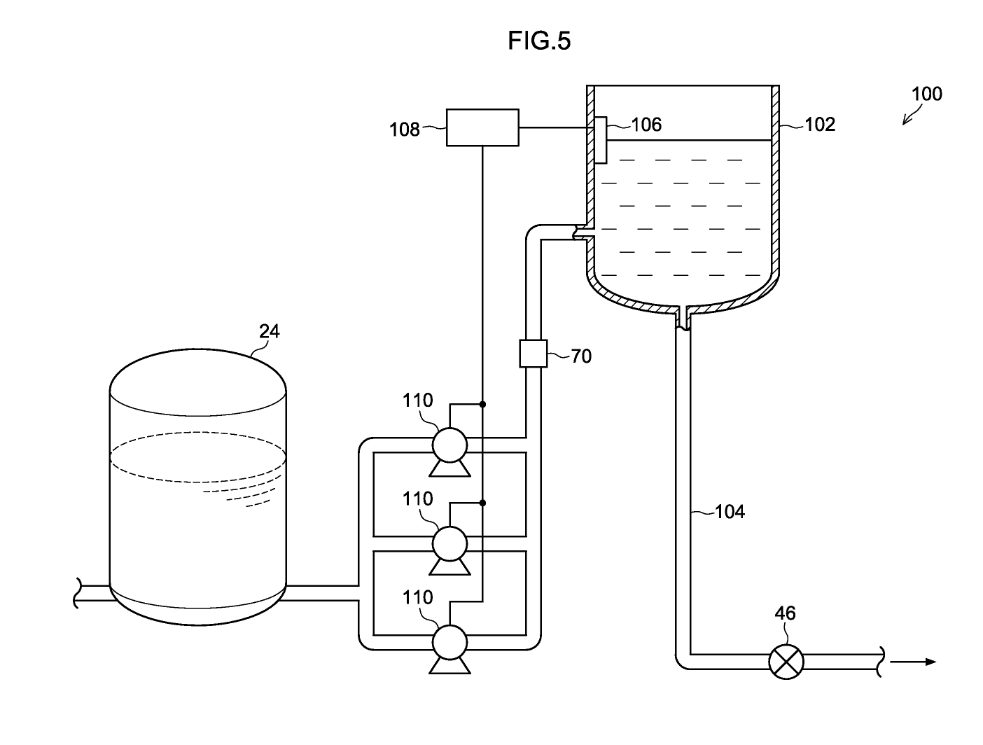

FIG. 5 illustrates a portion of an electrical system 100 according to a Comparative Example 1. The electrical system 100 includes a single recovery tank 24, a single elevated tank 102, and three pumps 110. The single elevated tank 102 is disposed higher than plural electrical devices, not illustrated in the drawings, connected to a supply pipe 104, and coolant liquid is supplied to the electrical devices utilizing gravity.

A water level sensor 106 is provided in the elevated tank 102. The water level sensor 106 detects the water level in the elevated tank 102, and outputs this to a controller 108. The controller 108 controls the feed rate of the three pumps 110 such that the water level of the elevated tank 102 input from the water level sensor 106 becomes a target water level value. Coolant liquid is thereby pumped up from the recovery tank 24 to the elevated tank 102.

In the electrical system 100 according to a Comparative Example 1, the designated flow rate of plural electrical devices 12 is securable by the remaining two pumps 110 even if one of the pumps 110 out of the three pumps 110 stops. Thus coolant liquid can be continuously supplied to the plural electrical devices even if one of the pumps 110 stops.

However, in the electrical system 100 according to a Comparative Example 1, the elevated tank 102 is bulky due to coolant liquid being supplied to the plural electrical devices from the single elevated tank 102. The manufacturing cost of the elevated tank 102 is accordingly high. The elevated tank 102 also needs to be installed higher than the electrical devices due to the elevated tank 102 utilizing gravity to discharge coolant liquid. The installation cost of the elevated tank 102 is accordingly high. Moreover, due to there being three pumps 110 to pump coolant liquid up from the recovery tank 24 for the single elevated tank 102, there is the possibility that control (the controller 108) of the three pumps 110 becomes complicated.

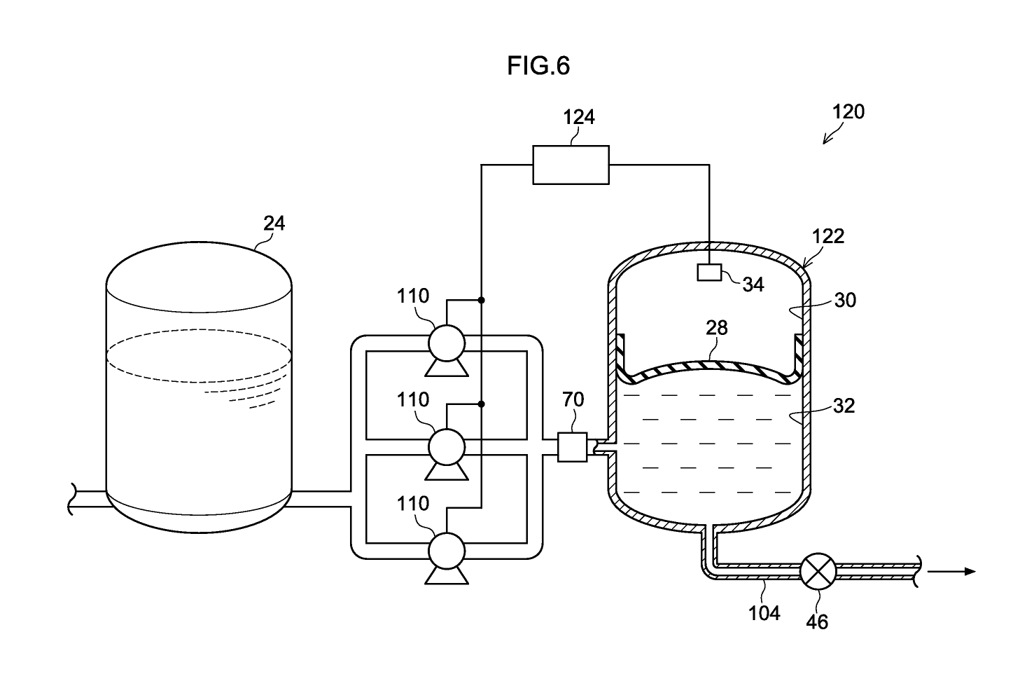

FIG. 6 illustrates an electrical system 120 according to a Comparative Example 2. The electrical system 120 is an electrical system in which the elevated tank 102, the water level sensor 106, and the controller 108 in the electrical system 100 according to the Comparative Example 1 have been replaced by a sealed expansion tank 122, a pressure sensor 34, and a controller 124.

The electrical system 120 according to the Comparative Example 2 enables installation cost to be reduced due to it being unnecessary to install the sealed expansion tank 122 at a high location. However, the sealed expansion tank 122 is bulky due to coolant being supplied to plural electrical devices from the single sealed expansion tank 122. The manufacturing cost of the sealed expansion tank 122 is accordingly high. Moreover, due to there being three pumps 110 to supply coolant liquid from the recovery tank 24 to the single sealed expansion tank 122, there is the possibility that control (the controller 124) of the three pumps 110 becomes complicated.

In contrast thereto, in the present embodiment, as illustrated in FIG. 1, the cooling units 20 are respectively connected to each of the plural electrical devices 12. This thereby enables more compact sealed expansion tanks 26 to be achieved than in the Comparative Examples 1, 2. The sealed expansion tanks 26 also do not need to be installed higher than the electrical devices 12 since coolant liquid is discharged by pressure in the gas chamber 30. A reduction in installation cost of the sealed expansion tanks 26 is accordingly achievable.

Moreover, in the present embodiment, for a single sealed expansion tank 26, the coolant liquid is supplied from the recovery tank 24 by a single pump 36, enabling control (the controller 38) of the pump 36 to be simplified compared to in the Comparative Examples 1, 2. Namely, each of the pumps 36 of the cooling units 20 is connected to the respective controller 38, and feeding of the pump 36 is controlled independently by the controller 38, enabling the control content of each of the controllers 38 to be simplified. It is however possible to control feeding of at least one but less than all of the pumps 36 among the cooling units 20 using a single controller 38.

Explanation next follows regarding a modified example of the above embodiment.

In the above embodiment, when all of the pumps 36 are being operated at the same time, the pressure of the gas chamber 30 of the sealed expansion tank 26 in each of the cooling units 20 is maintained in the vicinity of the same target pressure value. This accordingly makes it difficult for coolant liquid to flow from the reservoir 32 of each of the sealed expansion tanks 26 to the connection pipes 50, making the coolant liquid liable to stagnate in the connection pipes 50. If coolant liquid stagnates in the connection pipes 50, then the coolant liquid deteriorates more readily.

To address this, coolant liquid may be suppressed from stagnating in the connection pipes 50 by stopping at least one but less than all of the pumps 36 among the cooling units 20, or by reducing the feed rate of at least one but less than all of the pumps 36 among the cooling units 20.

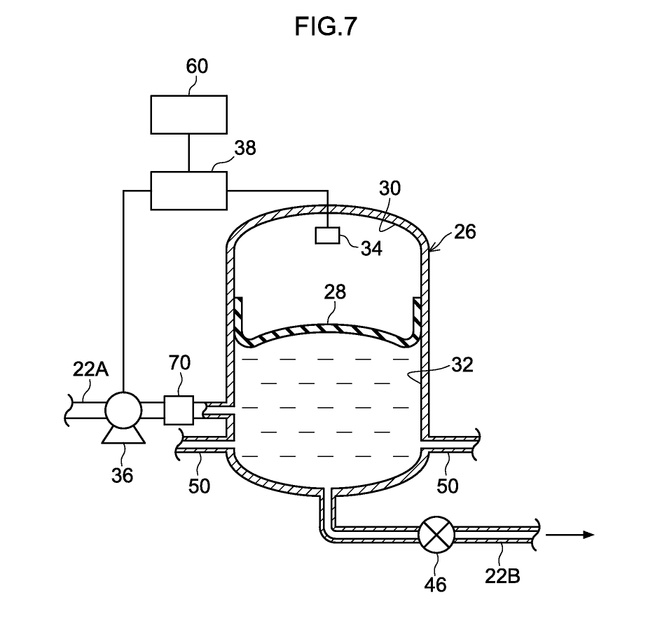

More specifically, as illustrated in FIG. 7, a feed rate controller 60 is electrically connected to the controller 38 of some of the cooling units 20. The feed rate controller 60 is, for example, actuated intermittently, and stops the pump 36 for a predetermined period of time, or reduces the flow rate of the pump 36 for a predetermined period of time. A pressure difference is thereby generated to the reservoirs 32 of the adjacent sealed expansion tanks 26, facilitating the flow of coolant liquid in the connection pipes 50. This thereby enables stagnation of coolant liquid in the connection pipes 50 to be suppressed.

The actuation timing of the feed rate controller 60 is variable as appropriate. The feed rate controller 60 may be actuated manually. Moreover the feed rate controller 60 may be incorporated in the controller 38. In such cases the controller 38 serves as an example of a feed rate controller.

In the above embodiment, an example is illustrated in which out of the plural pumps 36, a maximum feed rate U is set for each of the pumps 36 such that a total sum S of the maximum feed rates of at least one but less than all of the pumps 36 is equal to or greater than a total sum T of the designated flow rate of the coolant liquid for the plural electrical devices 12 (S≧T). There is, however, no limitation thereto. Suppose that the total sum S of the maximum feed rates of at least one but less than all of the pumps 36 were less than the total sum T of the designated flow rate of the coolant liquid for the plural electrical devices 12, more than a little coolant liquid would still be supplied by the remaining pumps 36 to the reservoir 32 connected to the stopped pump 36. As stated above, backflow of the coolant liquid in the supply pipe 22A is prevented by the non-reverse valve 70 even if the pump 36 is stopped. This thereby enables a situation to be avoided in which supply of the coolant liquid to the electrical devices 12 stops completely. Namely, even if the total sum S of the maximum feed rates of at least one but less than all of the pumps 36 is less than the total sum T of the designated flow rate of the coolant liquid for the plural electrical devices 12, redundancy can still be achieved in the pumps 36.

Moreover, in the above embodiment, a single electrical device 12 is connected to each of the cooling units 20, however there is no limitation thereto. Plural electrical devices 12 may be connected to each of the cooling units 20. It is also possible to have a different number of the electrical devices 12 for each of the cooling units 20.

An example is illustrated in the above embodiment of a case in which a single pump 36 is provided to each of the cooling units 20, however there is no limitation thereto. Plural pumps 36 may be provided for each of the cooling units 20.

An example is illustrated in the above embodiment of a case in which a controller 38 is provided to each of the cooling units 20, however a common controller 38 may be provided between plural cooling units 20.

In the above embodiment, an example is illustrated in which the sealed expansion tanks 26 of the cooling units 20 are connected together in a ring by the connection pipes 50; however there is no limitation thereto. For example, the sealed expansion tanks 26 of the cooling units 20 may be connected together in a linear series by the connection pipes 50. Connecting at least three of the sealed expansion tanks 26 of the cooling units 20 together in a ring by the connection pipes 50 enables the pumps 36 to be given redundancy efficiently.

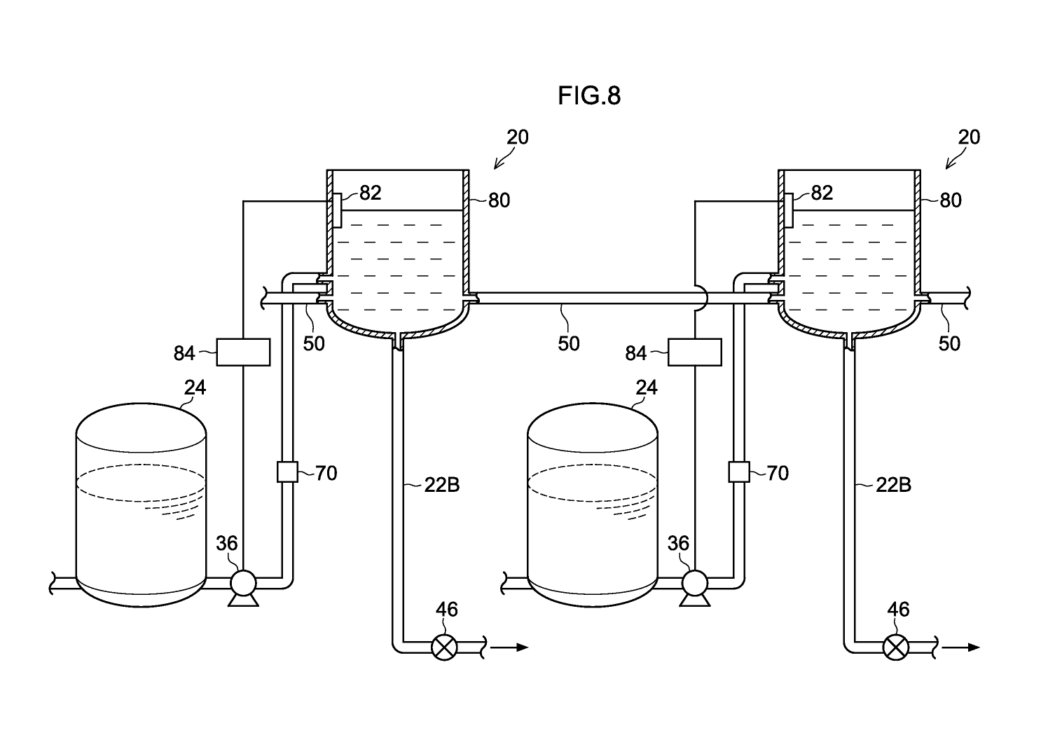

Moreover, in the above embodiment, an example has been illustrated in which there is a sealed expansion tank 26 provided for each of the cooling units 20; however there is no limitation thereto. For example, as illustrated in FIG. 8, an elevated tank 80 installed higher than the electrical devices 12 (see FIG. 2) may be provided to each of the cooling units 20. More specifically, a water level sensor 82 is provided in each of the elevated tanks 80. The water level sensor 82 detects the water level of coolant liquid stored in the elevated tank 80, and outputs this to a controller 84. The controller 84 controls the feed rate of the pump 36 such that the water level of the elevated tank 80 input from the water level sensor 82 becomes a target water level value. Moreover, the elevated tanks 80 of the adjacent cooling units 20 are connected together by the connection pipes 50. The elevated tanks 80 are an example of a tank.

In this case, for example, if one of the pumps 36 of the cooling units 20 stops, then the following occurs. Namely, the water level of the elevated tank 80 connected to the stopped pump 36 falls, and a water head pressure difference arises between that elevated tank 80 and the other elevated tanks 80. Coolant liquid is accordingly supplied from the other elevated tanks 80, via the connection pipes 50, to the elevated tank 80 that is connected to the stopped pump 36. This thereby enables similar advantageous effects to those of the above embodiment to be obtained.

In the above embodiment, an example is illustrated in which a recovery tank 24 is provided to each of the cooling units 20, however there is no limitation thereto. It is, for example, possible for one recovery tank to be common between plural cooling units 20. The recovery tank 24 may also be omitted as appropriate.

Explanation has been given above of embodiments of the technology disclosed herein, however the technology disclosed herein is not limited to the above embodiments. Appropriate combinations may also be made from the above embodiments and various modified examples, and obviously various embodiments may be implemented within a range not departing from the spirit of the technology disclosed herein.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electrical system comprising a plurality of sets of electrical devices and cooling units that respectively cool the electrical devices, wherein:
each of the cooling units comprises
a tank that is connected via a connection pipe to another tank of another of the cooling units and that stores coolant;
a heat exchanger that cools the coolant from the tank; and
a pump that feeds the coolant, which has been cooled by the heat exchanger, via a circulation pipe to the tank, the heat exchanger, and a cooler that cools a respective one of the electrical devices.

2. The electrical system of claim 1, wherein the tank of each of the cooling units comprises:
a reservoir that is separated from a gas chamber by a dividing membrane and that stores the coolant;
a detector that detects pressure in the gas chamber; and
a controller that varies a circulation rate of the coolant by the pump such that the pressure detected by the detector becomes a predetermined value.

3. The electrical system of claim 1, wherein:
a total of maximum feed rates of the coolant by at least one but less than all of the pumps among the cooling units is equal to or greater than a total of designated flow rates of the coolant to the plurality of electrical devices.

4. The electrical system of claim 1, further comprising:
a feed rate controller that controls the feed rate of the coolant by at least one but less than all of the pumps among the cooling units.

5. The electrical system of claim 2, wherein:
the electrical system includes at least three cooling units; and
the connection pipe connects each of the reservoirs of the tanks of the cooling units together in a ring.

6. The electrical system of claim 1, wherein:
in the electrical system, when feeding of the coolant by at least one but less than all of the pumps among the cooling units is stopped, the coolant flows via the connection pipe into the tank to which each of the stopped pumps is connected.

7. A control method for an electrical system including a plurality of sets of electrical devices and cooling units that cool the electrical devices, wherein each of the cooling units includes a tank that is connected via a connection pipe to another tank of another of the cooling units, and that stores a coolant in a reservoir that is separated from a gas chamber by a dividing membrane; a heat exchanger that cools the coolant from the tank; and a pump that feeds the coolant, which has been cooled by the heat exchanger, via a circulation pipe to the tank, the heat exchanger, and a cooler that cools a respective one of the electrical devices, the control method comprising:
detecting, by a detector of each of the cooling units, pressure in the gas chamber; and
varying, by a controller of each of the cooling units, a circulation rate of the coolant by the pump such that the pressure detected by the detector becomes a predetermined value.

8. The electrical system control method of claim 7, wherein a total of maximum feed rates of the coolant by at least one but less than all of the pumps among the cooling units is equal to or greater than a total of designated flow rates of the coolant to the plurality of electrical devices.

9. The electrical system control method of claim 7, wherein:
a feed rate controller that is connected to at least one but less than all of the pumps among the cooling units controls feed of the coolant by the connected pumps.

10. The electrical system control method of claim 7, wherein:
when feeding of the coolant by at least one but less than all of the pumps among the cooling units is stopped, the coolant flows via the connection pipe into the tank to which each of the stopped pumps is connected.

11. A cooling apparatus comprising a plurality of cooling units that each cool an electrical device, wherein:
each of the cooling units comprises
a tank that is connected via a connection pipe to another tank of another of the cooling units and that stores coolant;
a heat exchanger that cools the coolant from the tank; and
a pump that feeds the coolant, which has been cooled by the heat exchanger, via a circulation pipe to the tank, the heat exchanger, and a cooler that cools a respective one of the electrical devices.

12. The cooling apparatus of claim 11, wherein the tank of each of the cooling units comprises:
a reservoir that is separated from a gas chamber by a dividing membrane and that stores the coolant;
a detector that detects pressure in the gas chamber; and
a controller that varies a circulation rate of the coolant by the pump such that the pressure detected by the detector becomes a predetermined value.

13. The cooling apparatus of claim 11, wherein:
a total of maximum feed rates of the coolant by at least one but less than all of the pumps among the cooling units is equal to or greater than a total of designated flow rates of the coolant to the plurality of electrical devices.

14. The cooling apparatus of claim 11, further comprising:
a feed rate controller that controls the feed rate of the coolant by at least one but less than all of the pumps among the cooling units.

15. The cooling apparatus of claim 12, wherein:
the cooling apparatus includes at least three cooling units; and
the connection pipe connects each of the reservoirs of the tanks of the cooling units together in a ring.

16. The cooling apparatus of claim 11, wherein:
in the cooling apparatus, when feeding of the coolant by at least one but less than all of the pumps among the cooling units is stopped, the coolant flows via the connection pipe into the tank to which each of the stopped pumps is connected.
